(19) United States
(12) Patent Application Publication
(10) Pub. No.: US 2025/0015520 A1
(43) Pub. Date: Jan. 9, 2025

(54) FEMALE CONNECTOR AND CONNECTOR ASSEMBLY

(71) Applicant: LOTES CO., LTD, Keelung (TW)

(72) Inventors: Chien Chih Ho, Keelung (TW); Kal Quan Zhou, Keelung (TW)

(21) Appl. No.: 18/764,526

(22) Filed: Jul. 5, 2024

(30) Foreign Application Priority Data
Jul. 6, 2023 (CN) 202310830982.6

(51) Int. Cl. H01R 12/71; H01R 12/70; H01R 13/424; H01R 13/53

(52) U.S. Cl. CPC H01R 12/716; H01R 12/707; H01R 13/424; H01R 13/53

(57) ABSTRACT

A female connector includes a female body, first terminals provided at intervals in a lateral direction and second terminals provided at intervals in a longitudinal direction perpendicular to the lateral direction. The first and second terminals are fixed to the female body and intersect with each other to define multiple cavities, allowing heat dissipation. Each first terminal includes first elastic arms. Each second terminal includes second elastic arms. Each of the first and second elastic arms is provided with two arms and a connecting arm connecting them. Each of the two arms has a contact portion. For a first elastic arm and a second elastic arm facing a same cavity, the two contact portions of the first elastic arm are exposed to two adjacent cavities in the lateral direction, and the two contact portions of the second elastic arm are exposed to two adjacent cavities in the longitudinal direction.

### CROSS-REFERENCE TO RELATED PATENT APPLICATION

This non-provisional application claims priority to and the benefit of, pursuant to 35 U.S.C. § 119 (a), patent application Serial No. CN202310830982.6 filed in China on Jul. 6, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present invention relates to a female connector and a connector assembly, and particularly to a female connector and a connector assembly for transmitting large electrical currents.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

An electrical connector includes multiple independent conductive terminals and an insulating body fixing the conductive terminals. In an environment with large electrical currents, the conductive terminals transmitting the electrical currents tend to generate heat. In particular, in the process of continuously transmitting large electrical currents in a prolonged period, a significant amount of heat is generated. Further, the heat from the center of the electrical connector may not be dissipated in time, such that a temperature increase within the confined space of the electrical connector, which results in malfunction of the electrical connector.

Therefore, a heretofore unaddressed need to design an electrical connector exists in the art to address the aforementioned deficiencies and inadequacies.

### SUMMARY

In view of the deficiencies in the related art, the present invention is directed to an electrical connector, in which each power terminal include a plurality of elastic arms, and the power terminals intersect and connect longitudinally and laterally to form a plurality of accommodating cavities, thus facilitating the objective of rapid dissipation of heat at the center of the electrical connector.

To achieve the foregoing objective, the present invention adopts the following technical solutions.

A female connector is configured to mate with a male connector comprising a plurality of insertion portions. The female connector includes: a female body; and a plurality of power terminals, comprising a plurality of first terminals provided at intervals in a lateral direction and a plurality of second terminals provided at intervals in a longitudinal direction, wherein the lateral direction and the longitudinal direction are perpendicular to each other, the first terminals and the second terminals intersect with each other to define a plurality of cavities for insertion of the insertion portions, each of the first terminals comprises a first base and a plurality of first elastic arms connected to the first base, and each of the second terminals comprises a second base and a plurality of second elastic arms connected to the second base. The three consecutive adjacent first terminals of the first terminals and three consecutive adjacent second terminals of second terminals intersect to form four of the cavities, a first terminal located at a center of the three consecutive adjacent first terminals is provided with one of the first elastic arms corresponding to each of two adjacent cavities of the four of the cavities in the lateral direction, and a second terminal located at a center of the three consecutive adjacent second terminals is provided with one of the second elastic arms corresponding to each of two adjacent cavities of the four of the cavities in the longitudinal direction. For the first terminal located at the center of the three consecutive adjacent first terminals, each of the first elastic arms comprises a first arm, a second arm and a first connecting arm, the first arm and the second arm are provided at an interval in the longitudinal direction and are connected by the first connecting arm, a gap exists between the first connecting arm and the first base in a vertical direction, the vertical direction is perpendicular to the lateral direction and the longitudinal direction, the first arm is provided with a first contact portion, the second arm is provided with a second contact portion, the first contact portion is exposed toward one of the two adjacent cavities in the lateral direction, and the second contact portion is exposed toward the other of the two adjacent cavities in the lateral direction. For the second terminal located at the center of the three consecutive adjacent second terminals, each of the second elastic arms comprises a third arm, a fourth arm and a second connecting arm, the third arm and the fourth arm are provided at an interval in the lateral direction and are connected by the second connecting arm, a gap exists between the second connecting arm and the second base in the vertical direction, the third arm is provided with a third contact portion, the fourth arm is provided with a fourth contact portion, the third contact portion is exposed toward one of the two adjacent cavities in the longitudinal direction, and the fourth contact portion is exposed toward the other of the two adjacent cavities in the longitudinal direction.

In certain embodiments, the female body has two first frames provided at an interval in the lateral direction and two second frames provided at an interval in the longitudinal direction, the two first frames and the two second frames enclose to form a frame opening, two longitudinal ends of each of the first terminals are fixed to the two second frames, two lateral ends of each of the second terminals are fixed to the two first frames, and the cavities are provided to correspond to the frame opening.

In certain embodiments, a first gap is provided between two adjacent ones of the first elastic arms along the longitudinal direction, a width of the first gap increases upward from bottom thereof in the vertical direction, a second gap is provided between two adjacent ones of second elastic arms along the lateral direction, and a width of the second gap increases upward from bottom thereof in the vertical direction.

In certain embodiments, the first base and the first connecting arm are both flat plate shaped and located on a first plane, the first contact portion and the second contact portion protrude toward different ones of the cavities in the lateral direction relative to the first plane, the second base and the second connecting arm are both flat plate shaped and located on a second plane, the third contact portion and the fourth contact portion protrude toward different ones of the cavities in the longitudinal direction relative to the second plane.

In certain embodiments, for the two first elastic arms and the two second elastic arms corresponding to a same cavity of the cavities, one of the first contact portions, one of the second contact portions, one of the third contact portions and one of the fourth contact portions protrude towards the same cavity, the other of the first contact portions, the other of the second contact portions, the other of the third contact portions and the other of the fourth contact portions protrude away from the same cavity, and for the first elastic arm and the second elastic arm corresponding to the same cavity, the first contact portion, the second contact portion, the third contact portion and the fourth contact portion are arranged in a circumferential order along the same cavity, and the first contact portion and the third contact portion protrude toward the same cavity, or the second contact portion and the fourth contact portion protrude toward the same cavity.

In certain embodiments, the first contact portion, the second contact portion, the third contact portion and the fourth contact portion are provided at a same height.

In certain embodiments, the first connecting arm has a first guiding surface facing an adjacent cavity of the cavities in the lateral direction, the second connecting arm has a second guiding surface facing an adjacent cavity of the cavities in the longitudinal direction, and the first guiding surface and the second guiding surface provided in a same cavity of the cavities are configured to guide a corresponding one of the insertion portions to insert into the same cavity.

In certain embodiments, the first base comprises a plurality of sub-bases, the sub-bases and the first elastic arms are provided correspondingly in the vertical direction, a first groove exists between two adjacent ones of the sub-bases along the longitudinal direction, the first groove runs downward through the first base, the first groove bridges downward over the second base, each of the first terminals have a plurality of pins, each of the pins extends downward from a corresponding one of the sub-bases, and each of the pins protrudes downward relative to the second base in the vertical direction.

In certain embodiments, all of the first terminals are identical, and all of the second terminals are identical.

To achieve the foregoing objective, the present invention adopts the following technical solutions.

A female connector is configured to mate with a male connector comprising a plurality of insertion portions. The female connector includes: a female body; and a plurality of power terminals, comprising a plurality of first terminals provided at intervals in a lateral direction and a plurality of second terminals provided at intervals in a longitudinal direction, wherein the lateral direction and the longitudinal direction are perpendicular to each other, the first terminals and the second terminals intersect with each other to define a plurality of cavities for insertion of the insertion portions, only one of the first terminals is provided between two adjacent ones of the cavities in the lateral direction, only one of the second terminals is provided between two adjacent cavities in the longitudinal direction, each of the first terminals comprises a plurality of first elastic arms arranged along the longitudinal direction, each of the second terminals comprises a plurality of second elastic arms arranged along the lateral direction, each of the first elastic arms and the second elastic arms is provided with a plurality of contact portions, each of the first elastic arms protrudes with one of the contact portions toward a corresponding adjacent one of the cavities in the lateral direction, each of the second elastic arms protrudes with one of the contact portions toward a corresponding adjacent one of the cavities in the longitudinal direction, and the contact portions protruding toward the cavities are configured to be in contact with the insertion portions.

In certain embodiments, each of the first elastic arms and the second elastic arms is provided with two contact portions, for a first terminal located between two adjacent cavities in the lateral direction, the two contact portions of the first elastic arm thereof protrude toward two adjacent cavities in opposite directions in the lateral direction, and for a second terminal located between two adjacent cavities in the longitudinal direction, the two contact portions of the second elastic arm thereof protrude toward two adjacent cavities in opposite directions in the longitudinal direction.

In certain embodiments, the two contact portions of the first elastic arm are provided at an interval in the longitudinal direction, the two contact portions of the second elastic arm are provided at an interval in the lateral direction, the first elastic arm comprises a first connecting arm connecting the two contact portions of the first elastic arm, the second elastic arm comprises a second connecting arm connecting the two contact portions of the second elastic arm, the first connecting arm is provided with a first guiding surface facing the adjacent cavity in the lateral direction, and the second connecting arm is provided with a second guiding surface facing the adjacent cavity in the longitudinal direction, and the first guiding surface and the second guiding surface provided to face a same cavity of the cavities are configured to guide a corresponding one of the insertion portions to be inserted into the same cavity.

In certain embodiments, one of the first terminals and the second terminals is provided with a terminal pin protruding relative to the other of the first terminals and the second terminals in a vertical direction, and the vertical direction is perpendicular to the lateral direction and the longitudinal direction.

In certain embodiments, the female connector further includes a plurality of signal terminals provided on the female body. The female body comprises a power region and at least one signal region, the at least one signal region is located at a periphery of the power region, the power terminals are distributed in the power region, and the signal terminals are distributed in the at least one signal region.

In certain embodiments, the first terminals and the second terminals are formed by stamping different metal plates, a first gap is provided between two adjacent first elastic arms along the longitudinal direction, a second gap is provided between two adjacent second elastic arms along the lateral direction, the first gap is greater than a plate thickness of each of the second terminals, and the second gap is greater than a plate thickness of each of the first terminals.

To achieve the foregoing objective, the present invention adopts the following technical solutions.

A connector assembly includes: a female connector, comprising a female body and a plurality of female terminals provided on the female body, wherein the female terminals comprise a plurality of first terminals and a plurality of second terminals, the first terminals and the second terminals are configured to transmit power, the first terminals are arranged at intervals in a lateral direction, the second terminals are arranged at intervals in a longitudinal direction, the lateral direction and the longitudinal direction are perpendicular to each other, the first terminals and the second terminals intersect with each other to define a plurality of cavities, only one of the first terminals is provided between two adjacent ones of the cavities in the lateral direction, only one of the second terminals is provided between two adjacent cavities in the longitudinal direction, each of the first terminals comprises a plurality of first elastic arms, each of the second terminals comprises a plurality of second elastic arms, each of the first elastic arms and the second elastic arms comprises a plurality of contact portions, each of the first elastic arms protrudes with one of the contact portions toward a corresponding adjacent one of the cavities in the lateral direction, and each of the second elastic arms protrudes with one of the contact portions toward a corresponding adjacent one of the cavities in the longitudinal direction; and a male connector, configured to be inserted into the female connector, wherein the male connector comprises a male connector body and multiple male terminals disposed on the male connector body, the multiple male terminals comprise multiple insertion portions, one insertion portion corresponds to one of the multiple cavities, and electrically connected with the corresponding contact portions protruding into the one of the multiple cavities.

In certain embodiments, the connector assembly further includes a circuit board. The circuit board comprises at least one soldering pad, the male terminals are provided independently and at intervals in the lateral direction, each of the male terminals comprises a plurality of solder pins provided at intervals in the longitudinal direction, the solder pins of the male terminals are provided to align in the lateral direction and arranged in a plurality of rows in the longitudinal direction, and the solder pins in a same row are soldered to a same one of the at least one soldering pad by solders.

In certain embodiments, the connector assembly further includes a circuit board. The circuit board comprises at least one soldering pad, the male terminals are provided independently and at intervals in the longitudinal direction, each of the male terminals comprises a plurality of solder pins provided at intervals in the lateral direction, the solder pins of the male terminals are provided to align in the longitudinal direction and arranged in a plurality of rows in the lateral direction, and the solder pins in a same row are soldered to a same one of the at least one soldering pad by solders.

In certain embodiments, each of the cavities is correspondingly provided with four contact portions, and the four contact portions are provided at a same height and are in contact with a same one of the insertion portions.

In certain embodiments, each of the first elastic arms comprises a first arm, a second arm and a first connecting arm, the first arm and the second arm are provided at an interval in the longitudinal direction and connected by the first connecting arm, each of the first arm and the second arm is provided with one of the contact portions, the one of the contact portions of the first arm is defined as a first contact portion, the one of the contact portions of the second arm is defined as a second contact portion, for two adjacent cavities of the cavities in the lateral direction, the first contact portion and the second contact portion are exposed to different ones of two adjacent cavities in the lateral direction; each of the second elastic arms comprises a third arm, a fourth arm and a second connecting arm, the third arm and the fourth arm are provided at an interval in the lateral direction and connected by the second connecting arm, each of the third arm and the fourth arm is provided with one of the contact portions, the one of the contact portions of the third arm is defined as a third contact portion, the one of the contact portions of the fourth arm is defined as a fourth contact portion, and for two adjacent cavities of the cavities in the longitudinal direction, the third contact portion and the fourth contact portion are exposed to different ones of the two adjacent cavities in the longitudinal direction.

Compared with the related art, the female connector and connector assembly according to certain embodiments of the present invention have the following beneficial effects:

The first terminals provided at intervals in the lateral direction and the second terminals provided at intervals in the longitudinal direction intersect with each other, thus facilitating rapid dissipation of heat generated by the first terminals and the second terminals in the current transmission process.

For a first elastic arm and a second elastic arm facing a same cavity, the first contact portion is exposed toward one of the two adjacent cavities in the lateral direction, the second contact portion is exposed toward the other of the two adjacent cavities in the lateral direction, the third contact portion is exposed toward one of the two adjacent cavities in the longitudinal direction, and the fourth contact portion is exposed toward the other of the two adjacent cavities in the longitudinal direction. When an insertion portion is inserted into a corresponding cavity, the two ends of the first connecting arm along the longitudinal direction are subjected to two opposite forces in the lateral direction, resulting in twisting of the first connecting arm, and the two ends of the second connecting arm in the lateral direction are subjected to two opposite forces in the longitudinal direction, resulting in twisting of the second connecting arm, thus reducing the insertion force between the male connector and the female connector.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective view of a connector assembly according to certain embodiments of the present invention.

FIG. 2 is another perspective view of the connector assembly of FIG. 1 from a different viewing angle.

FIG. 3 is an exploded view of a female connector and a circuit board in the connector assembly as shown in FIG. 1.

FIG. 4 is a top view of the female connector as shown in FIG. 1.

FIG. 5 is a partial enlarged view of a portion A in FIG. 4.

FIG. 6 is a partial perspective view of a power terminal in FIG. 3 from another viewing angle.

FIG. 7 is a perspective view of a first terminal in FIG. 3.

FIG. 8 is a front view of the first terminal in FIG. 7.

FIG. 9 is a perspective view of a second terminal in FIG. 3.

FIG. 10 is a side view of the second terminal in FIG. 9.

FIG. 11 is an exploded view of a male connector and a circuit board in the connector assembly as shown in FIG. 1.

FIG. 12 is another perspective exploded view of the male connector and the circuit board in the connector assembly as shown in FIG. 1.

FIG. 13 is a partial sectional view of the male connector and the female connector in FIG. 1 being inserted with each other and sectioned on a plane along the vertical direction and the lateral direction.

FIG. 14 is a partial schematic view of the male connector and the female connector in FIG. 1 being inserted with each other and sectioned perpendicular to the vertical direction.

FIG. 15 is a top view of a first circuit board in FIG. 1.

FIG. 16 is a top view of a second circuit board in FIG. 1.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

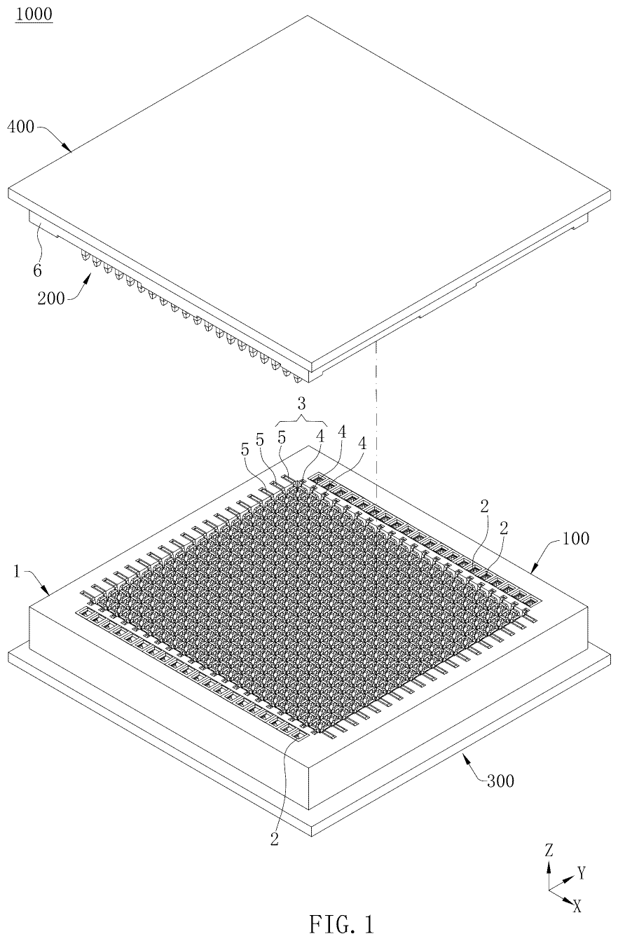

The description will be made as to the embodiments of the present invention in conjunction with the accompanying drawings in FIGS. 1-16. In accordance with the purposes of this invention, as embodied and broadly described herein, this invention, in one aspect, relates to a female connector and a connector assembly.

For ease of understanding, the lateral direction is denoted by X, the longitudinal direction is denoted by Y, and the vertical direction is denoted by Z. The lateral direction X, the longitudinal direction Y, and the vertical direction Z are mutually perpendicular to each other.

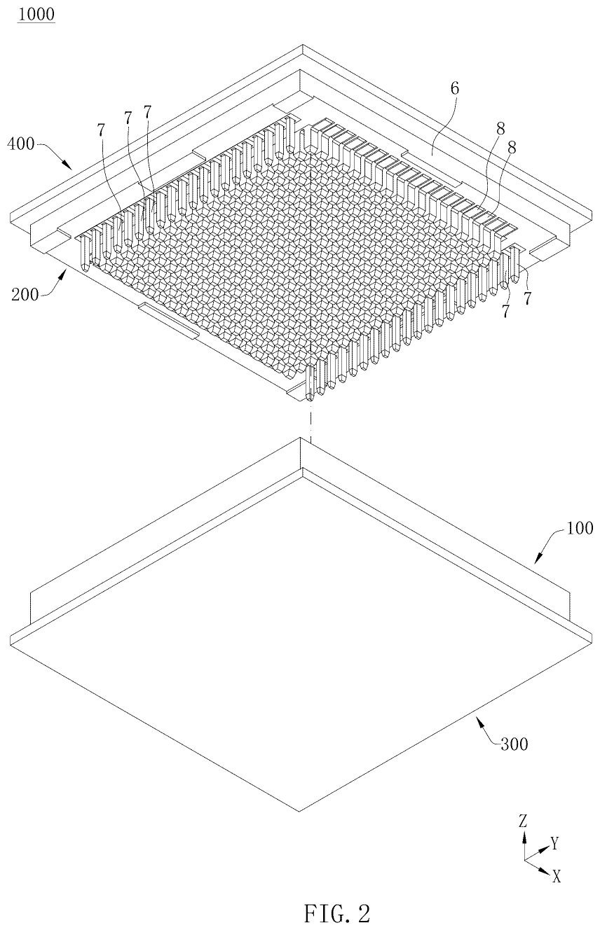

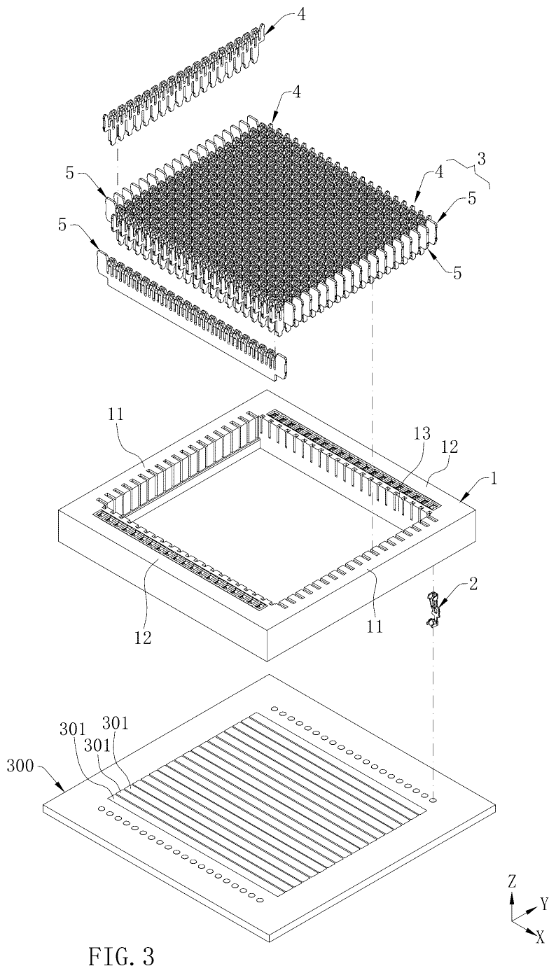

FIG. 1 to FIG. 2 show schematic views of the specific structure of the connector assembly 1000 according to certain embodiments of the present invention. The connector assembly 1000 includes a female connector 100 and a male connector 200 inserted into the female connector 100. FIG. 3 to FIG. 10 show specific structures of the female connector 100 according to a preferred embodiment of the present invention. The connector assembly 1000 further includes circuit boards respectively soldered to the female connector 100 and the male connector 200. The circuit board being soldered to the female connector 100 is defined as a first circuit board 300, and the circuit board being soldered to the male connector 200 is defined as a second circuit board 400.

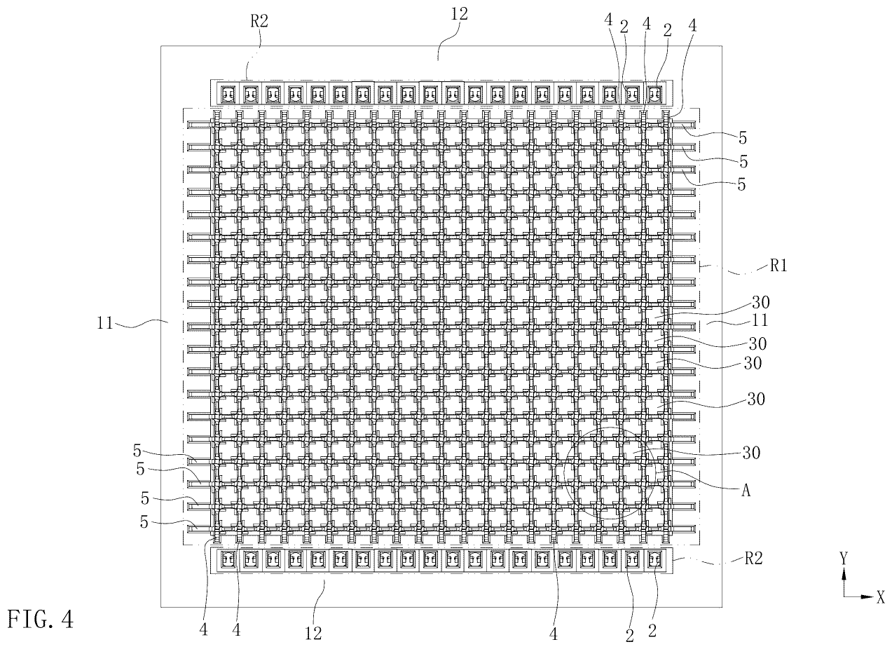

As shown in FIG. 1, FIG. 3 and FIG. 4, the female connector 100 includes a female body 1 and a plurality of power terminals 3 and a plurality of signal terminals 2 retained in the female body 1. The power terminals 3 and the signal terminals 2 are soldered to the first circuit board 300 by solders.

As shown in FIG. 3 and FIG. 4, the female body 1 is made of an insulating material. The female body 1 has two first frames 11 provided at an interval in the lateral direction and two second frames 12 provided at an interval in the longitudinal direction. The two first frames 11 and the two second frames 12 enclose to form a frame opening 13, and the frame opening 13 runs through the female body 1 in the vertical direction. The female body 1 includes a power region R1 and two signal regions R2. The two signal regions R2 are located at a periphery of the power region R1 and are located on two opposite sides of the power region R1 in the longitudinal direction. The power terminals 3 are distributed in the power region R1, and the signal terminals 2 are distributed in the signal regions R2. In other embodiments, the two signal regions R2 may be located at two opposite sides of the power region R1 in the lateral direction. Alternatively, it is possible to provide only one signal region R2, which is located at one side of the power region R1 in the longitudinal direction or at one side of the power region R1 in the lateral direction.

As shown in FIG. 3 and FIG. 4, the power terminals 3 include a plurality of first terminals 4 and a plurality of second terminals 5. The first terminals 4 have identical structures and are provided at intervals in a lateral direction, and the second terminals 5 have identical structures and are provided at intervals in a longitudinal direction. The first terminals 4 are formed by stamping a metal plate and have an elongated structure along the longitudinal direction, and the second terminals 5 are formed by stamping a metal plate and have an elongated structure along the lateral direction. The first terminals 4 may be produced using the same set of molds, and the second terminals 5 may be produced using the same set of molds. The first terminals 4 and the second terminals 5 intersect with each other in a “+” shape to define a plurality of cavities 30. The first terminals 4 is fixed to the two second frames 12 only at two ends in the longitudinal direction, and the second terminals 5 is fixed to the two first frames 11 only at two ends in the lateral direction, such that the first terminals 4 and the second terminals 5 are secured on the female body 1. The cavities 30 are provided corresponding to the frame opening 13, thus facilitating heat dissipation.

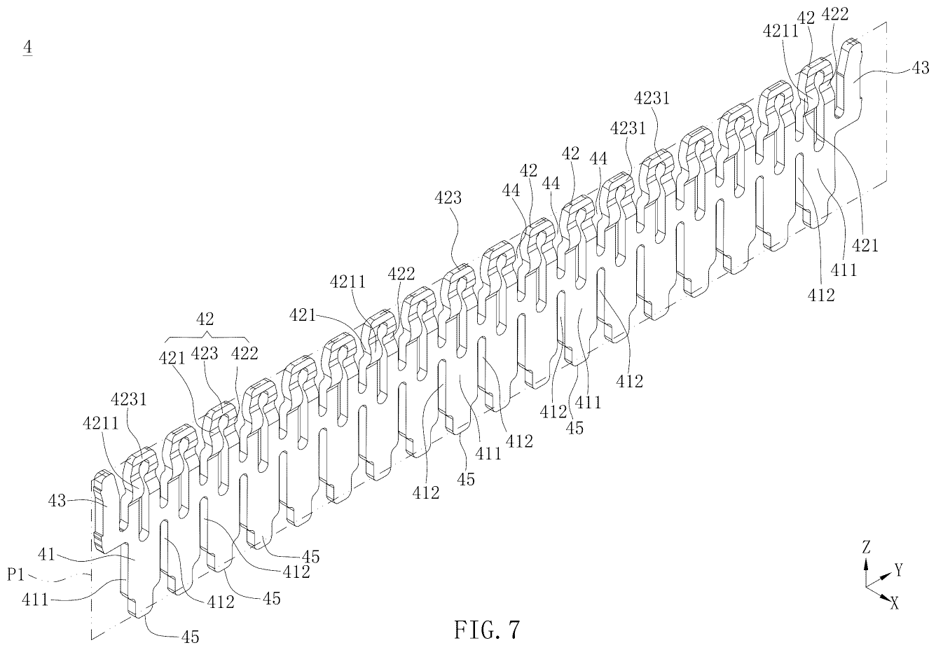

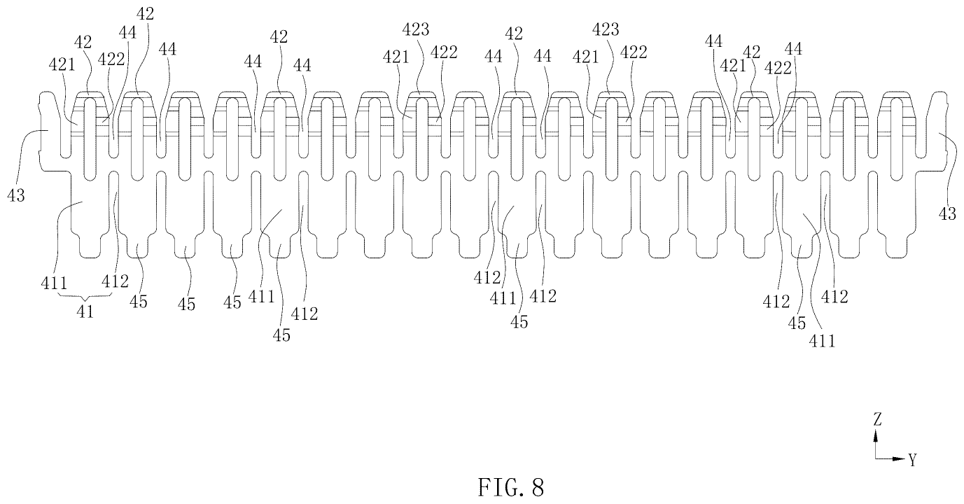

As shown in FIG. 7 and FIG. 8, each first terminal 4 includes a first base 41, a plurality of first elastic arms 42 connected to the first base 41, and two first fixing portions 43 located at two ends in the longitudinal direction. The first base 41 and the first fixing portions 43 are both flat plate shaped, and both extend vertically on a same plane. The first base 41 extends in the longitudinal direction. The two first fixing portions 43 are one-to-one correspondingly fixed to the two second frames 12. The first elastic arms 42 are arranged at intervals along the longitudinal direction. A first gap 44 is provided between any two adjacent first elastic arms 42 along the longitudinal direction. The first gap 44 is in an increasing trend upward from bottom thereof in the vertical direction. The first elastic arms 42 are connected to an upper end of the first base 41. The first elastic arms 42 of the first terminals 4 are provided to one-to-one align in the lateral direction, and the first gaps 44 of the first terminals 4 are provided to one-to-one align in the lateral direction.

As shown in FIG. 8, the first base 41 includes a plurality of sub-bases 411 arranged at intervals along the longitudinal direction. The sub-bases 411 and the first elastic arms 42 are provided correspondingly in the vertical direction, and a first groove 412 exists between any two adjacent sub-bases 411 along the longitudinal direction. The first groove 412 runs downward through the first base 41. Thus, the first groove 412 and one of the first gaps 44 above it are provided to align with each other in the vertical direction. The first grooves 412 of the first terminals 4 are provided to one-to-one align in the lateral direction.

As shown in FIG. 8, each first terminal 4 includes a plurality of pins 45, and each pin 45 is formed by extending downward from a corresponding sub-base 411 of each first terminal 4. Each pin 45 is also flat plate shaped to be soldered with the first circuit board 300 by a solder. The pins 45 of the first terminals 4 are provided to one-to-one align in the lateral direction. Thus, the pins 45 of the first terminals 4 are provided in a plurality of rows in the longitudinal direction, and the pins 45 in each row are arranged along the lateral direction. That is, each row includes a pin 45 on each of the first terminals 4.

As shown in FIG. 4 and FIG. 7, each first elastic arm 42 is provided to directly face at least one cavity 30 in the lateral direction. Specifically, in the lateral direction, each first elastic arm 42 of each of the two first terminals 4 located at the two outermost ends directly faces only one cavity 30, and each first elastic arm 42 of each of the first terminals 4 located at the middle directly faces two adjacent cavities 30 in the lateral direction. Each first elastic arm 42 includes a first arm 421, a second arm 422 and a first connecting arm 423. The first arm 421 and the second arm 422 are provided at an interval in the longitudinal direction, and are connected by the first connecting arm 423. A gap exists between the first connecting arm 423 and the first base 41 in the vertical direction, and the first base 41 and the first connecting arm 423 are both flat plate shaped and located on a same first plane P1.

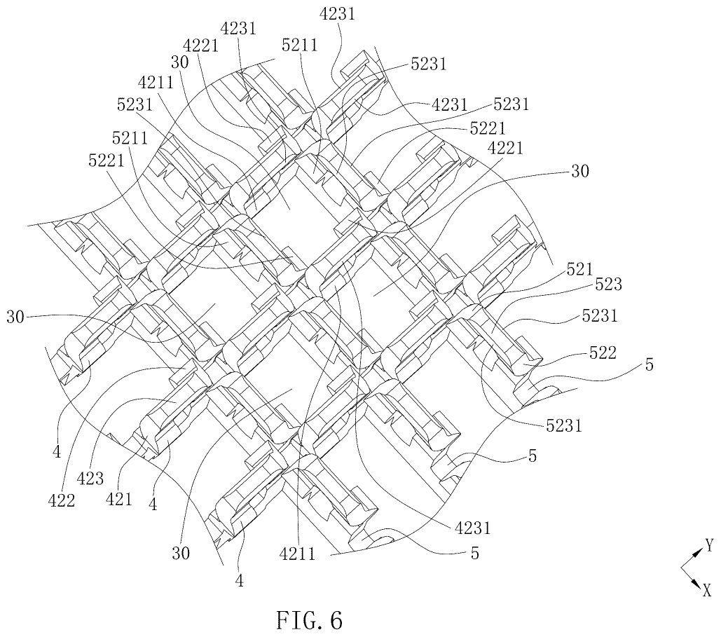

As shown in FIG. 4, FIG. 6 and FIG. 7, the first arm 421 has a first contact portion 4211, and the second arm 422 has a second contact portion 4221. Except for the two outermost first terminals 4 in the lateral direction, the first contact portion 4211 protrudes toward one of the two adjacent cavities 30 in the lateral direction from the first plane P1, and is exposed in the one of two adjacent cavities 30; and the second contact portion 4221 protrudes toward the other of the two adjacent cavities 30 in the lateral direction from the first plane P1, and is exposed in the other of the two adjacent cavities 30.

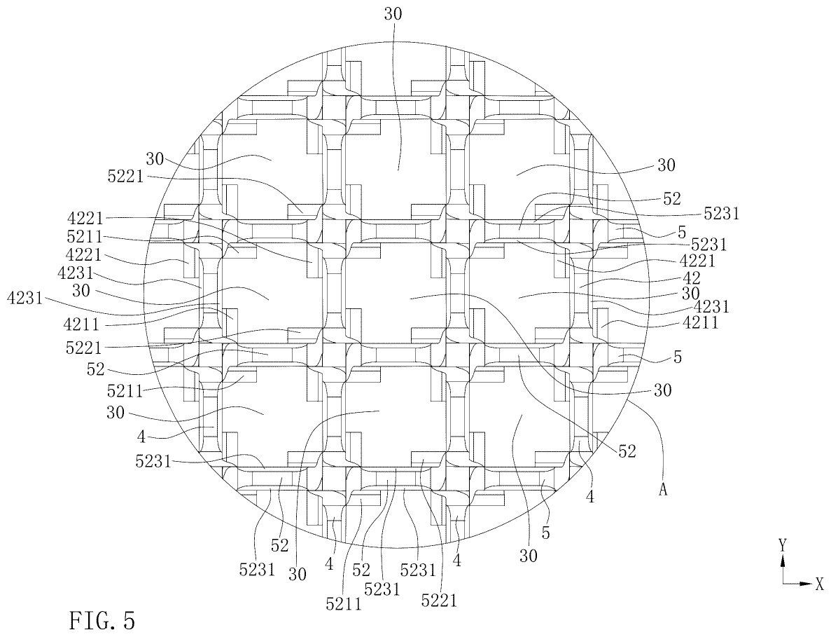

As shown in FIG. 5 and FIG. 6, the first connecting arm 423 is provided with a first guiding surface 4231 facing the adjacent cavities 30 in the lateral direction.

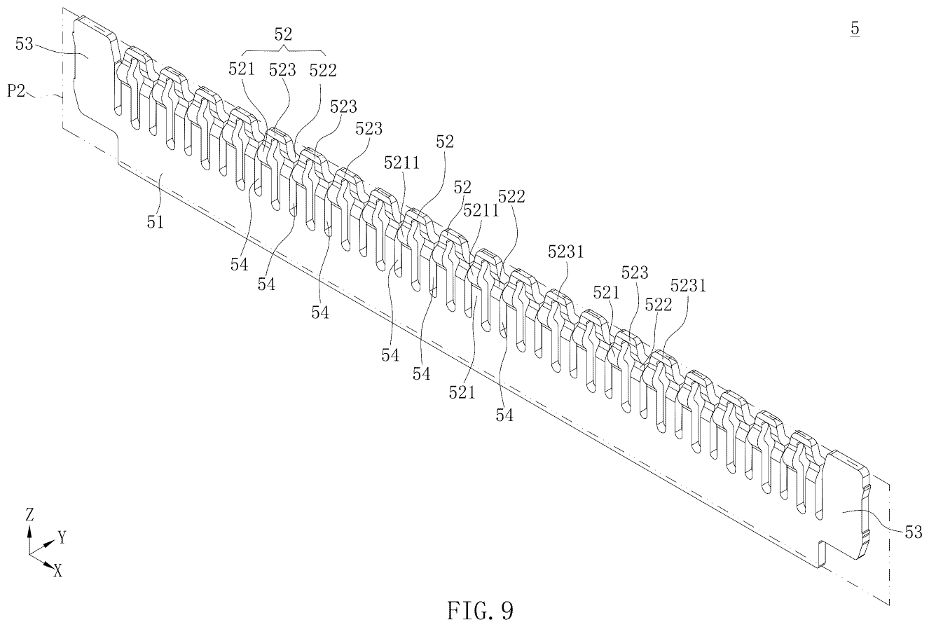

As shown in FIG. 3 and FIG. 9, each second terminal 5 includes a second base 51, a plurality of second elastic arms 52 connected to the second base 51 and two second fixing portions 53 located at two ends in the lateral direction. The second base 51 and the second fixing portions 53 are both flat plate shaped, and both extend vertically on a same plane. The second base 51 extends in the lateral direction. A first groove 412 of one of the first terminals 4 bridges downward on the second base 51 of one of the second terminals 5. Thus, the second base 51 of one of the second terminals 5 is simultaneously engaged with a plurality of first grooves 412 of the first terminals 4 aligned in the lateral direction, except for the two second terminals 5 located at the outermost ends in the longitudinal direction, which are not engaged with the first grooves 412. The pins 45 protrude downward relative to the second base 51 in the vertical direction, and the two second fixing portions 53 are one-to-one correspondingly fixed to the two first frames 11.

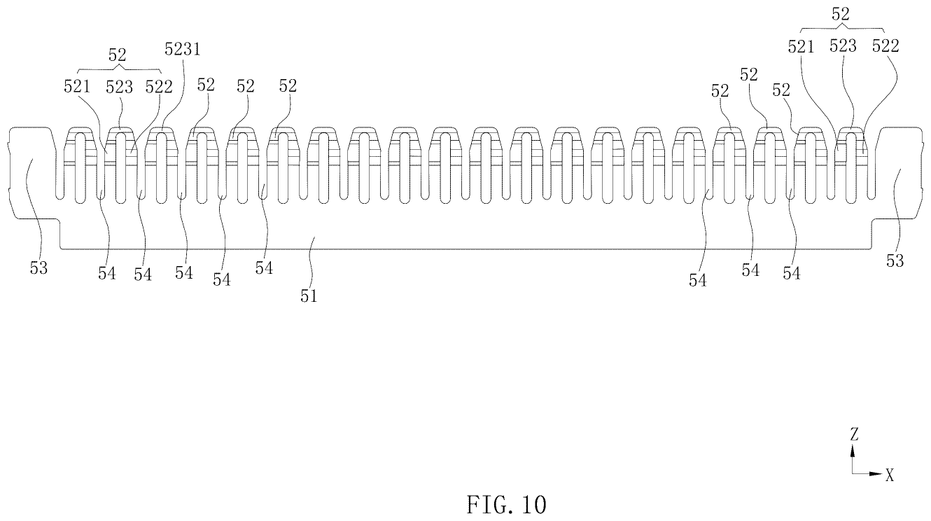

As shown in FIG. 10, the second elastic arms 52 are arranged at intervals in the lateral direction. A second gap 54 is provided between any two adjacent second elastic arms 52 in the lateral direction. The second gap 54 is in an increasing trend upward from bottom thereof in the vertical direction. The second elastic arms 52 are connected to an upper end of the second base 51. The second elastic arms 52 of the second terminals 5 are provided to one-to-one align in the longitudinal direction, and the second gaps 54 of the second terminals 5 are provided to one-to-one align in the longitudinal direction.

As shown in FIG. 4 and FIG. 9, each second elastic arm 52 directly faces at least one cavity 30 in the longitudinal direction. Specifically, in the longitudinal direction, each second elastic arm 52 of each of the two second terminals 5 located at the outermost ends directly faces only one cavity 30, and each second elastic arm 52 of each of the second terminal 5 located at the middle directly faces two adjacent cavities 30 in the longitudinal direction. Each second elastic arm 52 includes a third arm 521, a fourth arm 522 and a second connecting arm 523. The third arm 521 and the fourth arm 522 are provided at intervals in the lateral direction, and are connected by the second connecting arm 523. A gap exists between the second connecting arm 523 and the second base 51 in the vertical direction, and the second base 51 and the second connecting arm 523 are both flat plate shaped and located on a same second plane P2.

As shown in FIG. 4, FIG. 6 and FIG. 9, the third arm 521 has a third contact portion 5211, and the fourth arm 522 has a fourth contact portion 5221. Except for the two outermost second terminals 5 in the longitudinal direction, the third contact portion 5211 protrudes toward one of the two adjacent cavities 30 in the longitudinal direction from the second plane P2, and is exposed in the one of two adjacent cavities 30; and the fourth contact portion 5221 protrudes toward the other of the two adjacent cavities 30 in the longitudinal direction from the second plane P2, and is exposed in the other of the two adjacent cavities 30.

As shown in FIG. 5 and FIG. 6, the second connecting arm 523 is provided with a second guiding surface 5231 facing the adjacent cavities 30 in the longitudinal direction.

As shown in FIG. 5 and FIG. 6, for two first elastic arms 42 and two second elastic arms 52 corresponding to a same cavity 30, one of the first contact portions 4211, one of the second contact portions 4221, one of the third contact portions 5211 and one of the fourth contact portions 5221 protrude toward the same cavity 30, and the other of the first contact portions 4211, the other of the second contact portions 4221, the other of the third contact portions 5211 and the other of the fourth contact portions 5221 protrude away from the same cavity 30. For a first elastic arm 42 and a second elastic arm 52 corresponding to the same cavity 30, the first contact portion 4211, the second contact portion 4221, the third contact portion 5211 and the fourth contact portion 5221 are arranged in a circumferential order along the same cavity 30. The first contact portion 4211 and the third contact portion 5211 protrude toward the same cavity 30, and the second contact portion 4221 and the fourth contact portion 5221 protrude away from the same cavity 30. In this embodiment, the first contact portions 4211, the second contact portions 4221, the third contact portions 5211 and the fourth contact portions 5221 are provided at a same height. In other embodiments, for two first elastic arms 42 and two second elastic arms 52 corresponding to the same cavity 30, one of the first contact portions 4211, one of the second contact portions 4221, one of the third contact portions 5211 and one of the fourth contact portions 5221 protrude toward the same cavity 30, and the other of the first contact portions 4211, the other of the second contact portions 4221, the other of the third contact portions 5211 and the other of the fourth contact portions 5221 protrude away from the same cavity 30. For a first elastic arm 42 and a second elastic arm 52 corresponding to the same cavity 30, the first contact portion 4211, the second contact portion 4221, the third contact portion 5211 and the fourth contact portion 5221 are arranged in a circumferential order along the same cavity 30. The second contact portion 4221 and the fourth contact portion 5221 protrude toward the same cavity 30, and the first contact portion 4211 and the third contact portion 5211 protrude away from the same cavity 30.

In other embodiments, there are alternative configurations for the first contact portions 4211 and the second contact portions 4221 of the first elastic arm 42 as well as the cavities 30, and there are alternative configurations for the third contact portions 5211 and the fourth contact portions 5221 of the second elastic arms 52 as well as the cavities 30. These configurations are based on the premise that “for two first elastic arms 42 and two second elastic arms 52 corresponding to a same cavity 30, one of the first contact portions 4211, one of the second contact portions 4221, one of the third contact portions 5211 and one of the fourth contact portions 5221 protrude toward the same cavity 30, and the other of the first contact portions 4211, the other of the second contact portions 4221, the other of the third contact portions 5211 and the other of the fourth contact portions 5221 protrude away from the same cavity 30.” For example, for a first elastic arm 42 and a second elastic arm 52 corresponding to the same cavity 30, the first contact portion 4211, the second contact portion 4221, the third contact portion 5211 and the fourth contact portion 5221 are arranged in a circumferential order along the same cavity 30. The first contact portion 4211, the second contact portion 4221, the third contact portion 5211 and the fourth contact portion 5221 are provided at the same height. The first contact portion 4211 and the second contact portion 4221 protrude toward the same cavity 30. The third contact portion 5211 and the fourth contact portion 5221 also protrude toward the same cavity 30. In another example, for a first elastic arm 42 and a second elastic arm 52 corresponding to the same cavity 30, the first contact portion 4211, the second contact portion 4221, the third contact portion 5211 and the fourth contact portion 5221 are arranged in a circumferential order along the same cavity 30. The first contact portion 4211, the second contact portion 4221, the third contact portion 5211 and the fourth contact portion 5221 are provided at the same height. If the first contact portion 4211 and the second contact portion 4221 protrude toward different ones of the cavities 30 in the lateral direction relative to the first plane P1, which is identical to the preferred embodiment, the third contact portion 5211 and the fourth contact portion 5221 protrude toward the same cavity 30 in the longitudinal direction relative to the second plane P2. Alternatively, if the third contact portion 5211 and the fourth contact portion 5221 protrude toward different ones of the cavities 30 in the longitudinal direction relative to the second plane P2, which is identical to the preferred embodiment, the first contact portion 4211 and the second contact portion 4221 protrude toward the same cavity 30 in the lateral direction relative to the first plane P1. In a further example, for a first elastic arm 42 and a second elastic arm 52 corresponding to the same cavity 30, the first contact portion 4211 and the second contact portion 4221 are located at different heights in the vertical direction, and the third contact portion 5211 and the fourth contact portion 5221 are located at different heights in the vertical direction. The first contact portion 4211 and the second contact portion 4221 protrude toward different ones of the cavities 30 in the lateral direction, and the third contact portion 5211 and the fourth contact portion 5221 protrude toward different ones of the cavities 30 in the longitudinal direction.

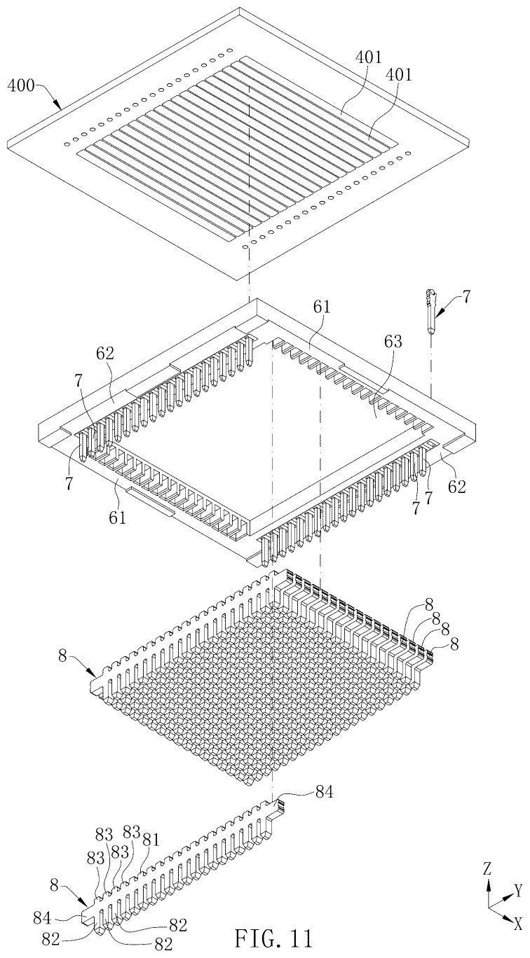

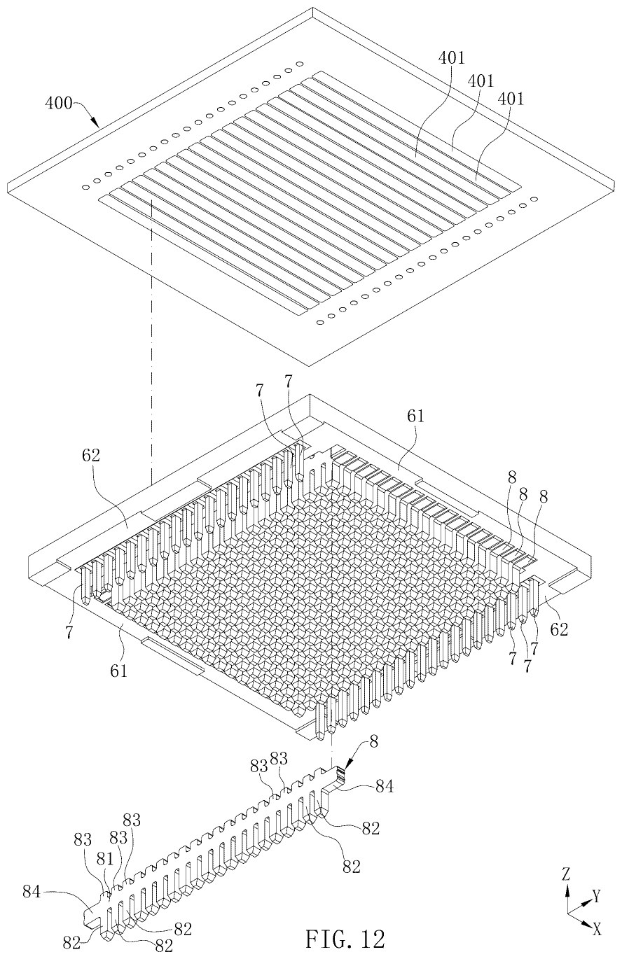

As shown in FIG. 11 and FIG. 12, the male connector 200 includes a male body 6, a plurality of mating terminals 7 and a plurality of male terminals 8. The mating terminals 7 and the male terminals 8 are provided on the male body 6. The mating terminals 7 and the male terminals 8 are soldered to the second circuit board 400. The mating terminals 7 are used to mate with the signal terminals 2, and the male terminals 8 mate with the power terminals 3.

As shown in FIG. 11, the male body 6 is made of an insulating material. The male body 6 has two third frames 61 provided at an interval in the lateral direction and two fourth frames 62 provided at an interval in the longitudinal direction. The two third frames 61 and the two fourth frames 62 enclose to form a window 63, and the window 63 runs vertically through the male body 6.

As shown in FIG. 12, the male terminals 8 are independent from each other and provided at intervals in the longitudinal direction. Each male terminal 8 is formed by stamping a metal plate and is overall flat plate shaped, and extends longitudinally in the lateral direction. Each male terminal 8 includes a main body 81, a plurality of insertion portions 82, a plurality of solder pins 83 and two engaging portions 84. The insertion portions 82 are provided at intervals in the lateral direction and are connected to a lower end of the main body 81. The solder pins 83 are provided at intervals in the lateral direction and are connected to an upper end of the main body 81. The insertion portions 82 and the solder pin 83 are arranged one-to-one correspondingly in the vertical direction. The two engaging portions 84 are provided at the two ends of the main body 81 in the lateral direction, and the two engaging portions 84 are one-to-one correspondingly fixed to the two third frames 61. The insertion portions 82 correspond to the location of the window 63 in the vertical direction and protrude downward out of the male body 6. The solder pins 83 of the male terminals 8 are provided to one-to-one align in the longitudinal direction. That is, the solder pins 83 of the male terminals 8 are arranged in a plurality of rows in the lateral direction, and the solder pins 83 in each row are arranged along the longitudinal direction. In other words, each row includes a solder pin 83 on each of the male terminals 8.

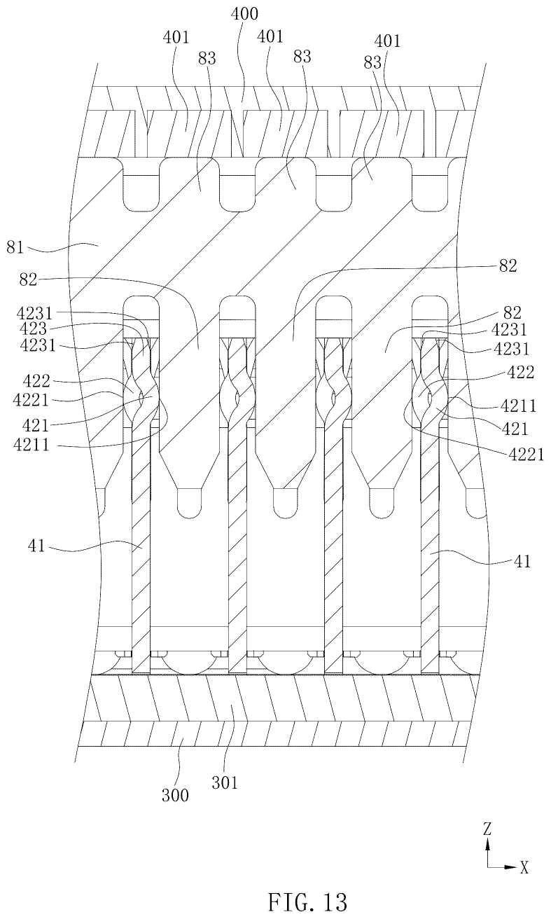

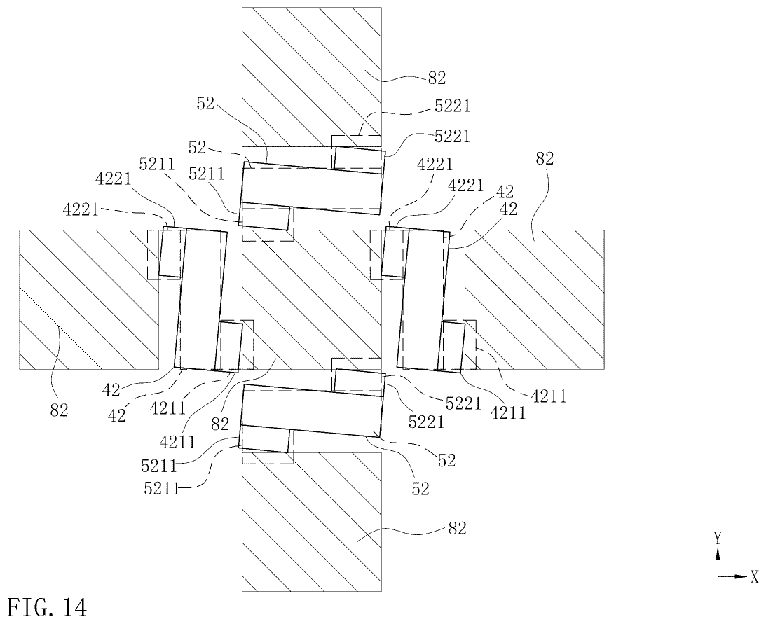

As shown in FIG. 13 and FIG. 14, when the male connector 200 and the female connector 100 are mated in the vertical direction, the first guiding surface 4231 and the second guiding surface 5231 provided in the same cavity 30 are used to guide the corresponding insertion portion 82 to be inserted into the same cavity 30. Each insertion portion 82 has a corresponding cavity 30 for insertion. In the lateral direction, the first contact portion 4211 and the second contact portion 4221 of the same first elastic arm 42 of a first terminal 4 at the middle are in contact with different insertion portions 82 in different cavities 30. The first arm 421 deviates toward a side opposite to the protruding side of the first contact portion 4211 in the lateral direction, such that the second contact portion 4221 moves toward a direction away from the corresponding insertion portion 82 in the lateral direction, and the insertion force given by the second contact portion 4221 to the corresponding insertion portion 82 is reduced. The second arm 422 deviates toward a side opposite to the protruding side of the second contact portion 4221 in the lateral direction, such that the first contact portion 4211 moves toward a direction away from the corresponding insertion portion 82 in the lateral direction, and the insertion force given by the first contact portion 4211 to the corresponding insertion portion 82 is reduced. The two ends of the first connecting arm 423 in the longitudinal direction respectively connected to the first arm 421 and the second arm 422, and since the first arm 421 and the second arm 422 deviate toward opposite directions, the first connecting arm 423 rotates clockwise or counterclockwise horizontally. In the longitudinal direction, the third contact portion 5211 and the fourth contact portion 5221 of the same second elastic arm 52 of a second terminal 5 at the middle are in contact with different insertion portions 82 in different cavities 30. The third arm 521 deviates toward a side opposite to the protruding side of the third contact portion 5211 in the longitudinal direction, such that the fourth contact portion 5221 moves toward a direction away from the corresponding insertion portion 82 in the longitudinal direction, and the insertion force given by the fourth contact portion 5221 to the corresponding insertion portion 82 is reduced. The fourth arm 522 deviates toward a side opposite to the protruding side of the fourth contact portion 5221 in the longitudinal direction, such that the third contact portion 5211 moves toward a direction away from the corresponding insertion portion 82 in the longitudinal direction, and the insertion force given by the third contact portion 5211 to the corresponding insertion portion 82 is reduced. The two ends of the second connecting arm 523 in the lateral direction respectively connected to the third arm 521 and the fourth arm 522, and since the third arm 521 and the fourth arm 522 deviate toward opposite directions, the second connecting arm 523 rotates clockwise or counterclockwise horizontally.

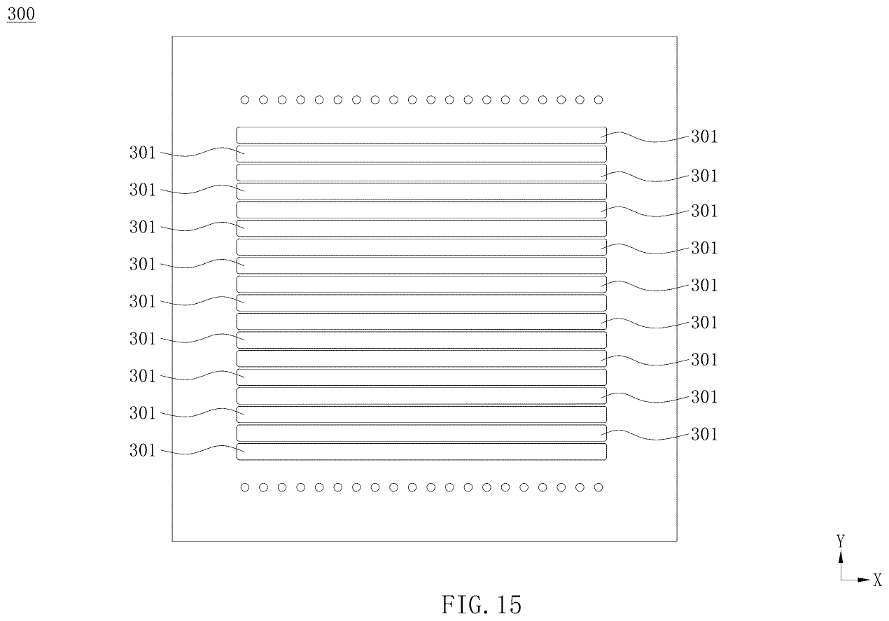

As shown in FIG. 15, an upper surface of the first circuit board 300 is provided with a plurality of conductive pads 301. The conductive pads 301 are provided at intervals along the longitudinal direction. Each conductive pad 301 extends longitudinally in the lateral direction and is soldered to a row of the pins 45 of the first terminals 4 along the lateral direction. In other embodiments, the first circuit board 300 may be provided with only a single relatively large conductive pad 301, and all of the pins 45 are soldered to the same conductive pad 301 by solders. Alternatively, the conductive pads 301 may be provided at intervals along the lateral direction, and each conductive pad 301 extends longitudinally in the longitudinal direction and is soldered to all of the terminal pins 45 of the same first terminal 4 by solders.

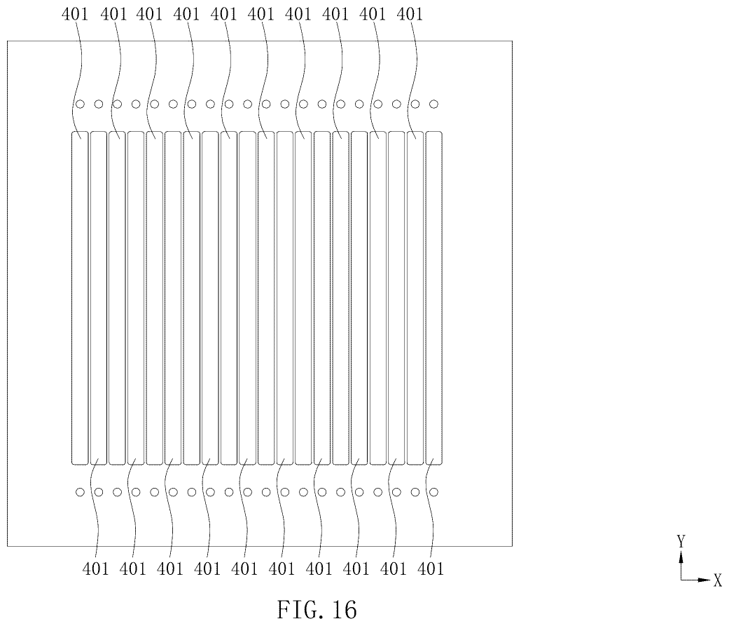

As shown in FIG. 16, an upper surface of the second circuit board 400 is provided with a plurality of soldering pads 401. The soldering pads 401 are provided at intervals along the lateral direction. Each soldering pad 401 extends longitudinally along the longitudinal direction and is soldered to a row of the solder pins 83 of the male terminals 8 along the longitudinal direction. That is, each soldering pad 401 serially connects the male terminals 8 that are independent from each other. In other embodiments, the male terminals 8 may be independent from each other and provided at intervals along the lateral direction, the insertion portions 82 and the solder pins 83 of each male terminal 8 are arranged along the longitudinal direction, and the two engaging portions 84 are one-to-one correspondingly fixed to the two fourth frames 62. Other structures are identical to those in the aforementioned embodiment. Thus, the solder pins 83 of the male terminals 8 are provided to one-to-one align in the lateral direction. That is, the solder pins 83 of the male terminals 8 are provided in a plurality of rows in the longitudinal direction, and the solder pins 83 in each row are arranged along the lateral direction. In other words, each row includes a solder pin 83 on each of the male terminals 8. The corresponding soldering pads 401 are provided at intervals along the longitudinal direction. Each soldering pad 401 extends longitudinally along the lateral direction and is soldered to a row of the solder pins 83 of the male terminals 8 along the lateral direction. That is, each soldering pad 401 serially connects the male terminals 8 that are independent from each other. Alternatively, the second circuit board 400 may be provided with only a single relatively large soldering pad 401, and all of the solder pins 83 are soldered to the same soldering pad 401 by solders.

In sum, the female connector and the connector assembly according to certain embodiments of the present invention have the following beneficial effects:
(1) The first terminals 4 provided at intervals in the lateral direction and the second terminals 5 provided at intervals in the longitudinal direction intersect with each other, thus facilitating rapid dissipation of heat generated by the first terminals 4 and the second terminals 5 in the current transmission process.
(2) The first gap 44 and the second gap 54 are in an increasing trend upward from bottom thereof in the vertical direction, thus preventing from interferences between the first elastic arms 42 and the adjacent second terminals 5 and between the second elastic arms 52 and the adjacent first terminals 4 in the process of deformation of the first elastic arms 42 and the second elastic arms 52 due to force.
(3) The first contact portion 4211 and the second contact portion 4221 protrude toward different ones of the adjacent cavities 30 in the lateral direction, and the third contact portion 5211 and the fourth contact portion 5221 protrude toward different ones of the adjacent cavities 30 in the longitudinal direction. When an insertion portion 82 is inserted into a corresponding cavity 30, the two ends of the first connecting arm 423 along the longitudinal direction are subjected to two opposite forces in the lateral direction, resulting in twisting of the first connecting arm 423, and the two ends of the second connecting arm 523 along the lateral direct are subjected to two opposite forces in the lateral direction, resulting in twisting of the second connecting arm 523, thus reducing the insertion force between the male connector 200 and the female connector 100.
(4) The first connecting arm 423 is provided with a first guiding surface 4231 facing the adjacent cavity 30 in the lateral direction, and the second connecting arm 523 is provided with a second guiding surface 5231 facing the adjacent cavity 30 in the longitudinal direction, thus facilitating the guidance of the corresponding insertion portions 82 to insert into the corresponding cavities 30.
5) All of first terminals 4 have identical structures, and all second terminals 5 have identical structures, thus reducing the manufacturing cost of the female connector 100.
6) The solder pins 83 of different male terminals 8 and in the same row are soldered to a same soldering pad 401, thus facilitating heat transfer between different male terminals 8, transferring heat of the male terminal 8 at the center toward the male terminals 8 at the edges, and accelerating heat dissipation.

The above description is only an explanation of preferred embodiments of the invention, and is not intended to limit the scope of the invention. Therefore, all equivalent technical changes made based on the content of this specification and drawings are included within the scope of the invention.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A female connector, configured to mate with a male connector comprising a plurality of insertion portions, the female connector comprising:
a female body; and
a plurality of power terminals, comprising a plurality of first terminals provided at intervals in a lateral direction and a plurality of second terminals provided at intervals in a longitudinal direction, wherein the lateral direction and the longitudinal direction are perpendicular to each other, the first terminals and the second terminals intersect with each other to define a plurality of cavities for insertion of the insertion portions, each of the first terminals comprises a first base and a plurality of first elastic arms connected to the first base, and each of the second terminals comprises a second base and a plurality of second elastic arms connected to the second base;
wherein three consecutive adjacent first terminals of the first terminals and three consecutive adjacent second terminals of second terminals intersect to form four of the cavities, a first terminal located at a center of the three consecutive adjacent first terminals is provided with one of the first elastic arms corresponding to each of two adjacent cavities of the four of the cavities in the lateral direction, and a second terminal located at a center of the three consecutive adjacent second terminals is provided with one of the second elastic arms corresponding to each of two adjacent cavities of the four of the cavities in the longitudinal direction;
wherein for the first terminal located at the center of the three consecutive adjacent first terminals, each of the first elastic arms comprises a first arm, a second arm and a first connecting arm, the first arm and the second arm are provided at an interval in the longitudinal direction and are connected by the first connecting arm, a gap exists between the first connecting arm and the first base in a vertical direction, the vertical direction is perpendicular to the lateral direction and the longitudinal direction, the first arm is provided with a first contact portion, the second arm is provided with a second contact portion, the first contact portion is exposed toward one of the two adjacent cavities in the lateral direction, and the second contact portion is exposed toward the other of the two adjacent cavities in the lateral direction;
wherein for the second terminal located at the center of the three consecutive adjacent second terminals, each of the second elastic arms comprises a third arm, a fourth arm and a second connecting arm, the third arm and the fourth arm are provided at an interval in the lateral direction and are connected by the second connecting arm, a gap exists between the second connecting arm and the second base in the vertical direction, the third arm is provided with a third contact portion, the fourth arm is provided with a fourth contact portion, the third contact portion is exposed toward one of the two adjacent cavities in the longitudinal direction, and the fourth contact portion is exposed toward the other of the two adjacent cavities in the longitudinal direction.

2. The female connector according to claim 1, wherein the female body has two first frames provided at an interval in the lateral direction and two second frames provided at an interval in the longitudinal direction, the two first frames and the two second frames enclose to form a frame opening, two longitudinal ends of each of the first terminals are fixed to the two second frames, two lateral ends of each of the second terminals are fixed to the two first frames, and the cavities are provided to correspond to the frame opening.

3. The female connector according to claim 1, wherein a first gap is provided between two adjacent ones of the first elastic arms along the longitudinal direction, a width of the first gap increases upward from bottom thereof in the vertical direction, a second gap is provided between two adjacent ones of second elastic arms along the lateral direction, and a width of the second gap increases upward from bottom thereof in the vertical direction.

4. The female connector according to claim 1, wherein the first base and the first connecting arm are both flat plate shaped and located on a first plane, the first contact portion and the second contact portion protrude toward different ones of the cavities in the lateral direction relative to the first plane, the second base and the second connecting arm are both flat plate shaped and located on a second plane, the third contact portion and the fourth contact portion protrude toward different ones of the cavities in the longitudinal direction relative to the second plane.

5. The female connector according to claim 1, wherein for the two first elastic arms and the two second elastic arms corresponding to a same cavity of the cavities, one of the first contact portions, one of the second contact portions, one of the third contact portions and one of the fourth contact portions protrude towards the same cavity, the other of the first contact portions, the other of the second contact portions, the other of the third contact portions and the other of the fourth contact portions protrude away from the same cavity, and for the first elastic arm and the second elastic arm corresponding to the same cavity, the first contact portion, the second contact portion, the third contact portion and the fourth contact portion are arranged in a circumferential order along the same cavity, and the first contact portion and the third contact portion protrude toward the same cavity, or the second contact portion and the fourth contact portion protrude toward the same cavity.

6. The female connector according to claim 5, wherein the first contact portion, the second contact portion, the third contact portion and the fourth contact portion are provided at a same height.

7. The female connector according to claim 1, wherein the first connecting arm has a first guiding surface facing an adjacent cavity of the cavities in the lateral direction, the second connecting arm has a second guiding surface facing an adjacent cavity of the cavities in the longitudinal direction, and the first guiding surface and the second guiding surface provided in a same cavity of the cavities are configured to guide a corresponding one of the insertion portions to insert into the same cavity.

8. The female connector according to claim 1, wherein the first base comprises a plurality of sub-bases, the sub-bases and the first elastic arms are provided correspondingly in the vertical direction, a first groove exists between two adjacent ones of the sub-bases along the longitudinal direction, the first groove runs downward through the first base, the first groove bridges downward over the second base, each of the first terminals have a plurality of pins, each of the pins extends downward from a corresponding one of the sub-bases, and each of the pins protrudes downward relative to the second base in the vertical direction.

9. The female connector according to claim 1, wherein all of the first terminals are identical, and all of the second terminals are identical.

10. A female connector, configured to mate with a male connector comprising a plurality of insertion portions, the female connector comprising:
a female body; and
a plurality of power terminals, comprising a plurality of first terminals provided at intervals in a lateral direction and a plurality of second terminals provided at intervals in a longitudinal direction, wherein the lateral direction and the longitudinal direction are perpendicular to each other, the first terminals and the second terminals intersect with each other to define a plurality of cavities for insertion of the insertion portions, only one of the first terminals is provided between two adjacent ones of the cavities in the lateral direction, only one of the second terminals is provided between two adjacent cavities in the longitudinal direction, each of the first terminals comprises a plurality of first elastic arms arranged along the longitudinal direction, each of the second terminals comprises a plurality of second elastic arms arranged along the lateral direction, each of the first elastic arms and the second elastic arms is provided with a plurality of contact portions, each of the first elastic arms protrudes with one of the contact portions toward a corresponding adjacent one of the cavities in the lateral direction, each of the second elastic arms protrudes with one of the contact portions toward a corresponding adjacent one of the cavities in the longitudinal direction, and the contact portions protruding toward the cavities are configured to be in contact with the insertion portions.

11. The female connector according to claim 10, wherein each of the first elastic arms and the second elastic arms is provided with two contact portions, for a first terminal located between two adjacent cavities in the lateral direction, the two contact portions of the first elastic arm thereof protrude toward the two adjacent cavities in opposite directions in the lateral direction, and for a second terminal located between two adjacent cavities in the longitudinal direction, the two contact portions of the second elastic arm thereof protrude toward the two adjacent cavities in opposite directions in the longitudinal direction.

12. The female connector according to claim 11, wherein the two contact portions of the first elastic arm are provided at an interval in the longitudinal direction, the two contact portions of the second elastic arm are provided at an interval in the lateral direction, the first elastic arm comprises a first connecting arm connecting the two contact portions of the first elastic arm, the second elastic arm comprises a second connecting arm connecting the two contact portions of the second elastic arm, the first connecting arm is provided with a first guiding surface facing the adjacent cavity in the lateral direction, and the second connecting arm is provided with a second guiding surface facing the adjacent cavity in the longitudinal direction, and the first guiding surface and the second guiding surface provided to face a same cavity of the cavities are configured to guide a corresponding one of the insertion portions to be inserted into the same cavity.

13. The female connector according to claim 10, wherein one of the first terminals and the second terminals is provided with a terminal pin protruding relative to the other of the first terminals and the second terminals in a vertical direction, and the vertical direction is perpendicular to the lateral direction and the longitudinal direction.

14. The female connector according to claim 10, further comprising a plurality of signal terminals provided on the female body, wherein the female body comprises a power region and at least one signal region, the at least one signal region is located at a periphery of the power region, the power terminals are distributed in the power region, and the signal terminals are distributed in the at least one signal region.

15. The female connector according to claim 10, wherein the first terminals and the second terminals are formed by stamping different metal plates, a first gap is provided between two adjacent first elastic arms along the longitudinal direction, a second gap is provided between two adjacent second elastic arms along the lateral direction, the first gap is greater than a plate thickness of each of the second terminals, and the second gap is greater than a plate thickness of each of the first terminals.

16. A connector assembly, comprising:
a female connector, comprising a female body and a plurality of female terminals provided on the female body, wherein the female terminals comprise a plurality of first terminals and a plurality of second terminals, the first terminals and the second terminals are configured to transmit power, the first terminals are arranged at intervals in a lateral direction, the second terminals are arranged at intervals in a longitudinal direction, the lateral direction and the longitudinal direction are perpendicular to each other, the first terminals and the second terminals intersect with each other to define a plurality of cavities, only one of the first terminals is provided between two adjacent ones of the cavities in the lateral direction, only one of the second terminals is provided between two adjacent cavities in the longitudinal direction, each of the first terminals comprises a plurality of first elastic arms, each of the second terminals comprises a plurality of second elastic arms, each of the first elastic arms and the second elastic arms comprises a plurality of contact portions, each of the first elastic arms protrudes with one of the contact portions toward a corresponding adjacent one of the cavities in the lateral direction, and each of the second elastic arms protrudes with one of the contact portions toward a corresponding adjacent one of the cavities in the longitudinal direction; and
a male connector, configured to be inserted into the female connector, wherein the male connector comprises a male connector body and multiple male terminals disposed on the male connector body, the multiple male terminals comprise multiple insertion portions, one insertion portion corresponds to one of the multiple cavities, and electrically connected with the corresponding contact portions protruding into the one of the multiple cavities.

17. The connector assembly according to claim 16, further comprising a circuit board, wherein the circuit board comprises at least one soldering pad, the male terminals are provided independently and at intervals in the lateral direction, each of the male terminals comprises a plurality of solder pins provided at intervals in the longitudinal direction, the solder pins of the male terminals are provided to align in the lateral direction and arranged in a plurality of rows in the longitudinal direction, and the solder pins in a same row are soldered to a same one of the at least one soldering pad by solders.

18. The connector assembly according to claim 16, further comprising a circuit board, wherein the circuit board comprises at least one soldering pad, the male terminals are provided independently and at intervals in the longitudinal direction, each of the male terminals comprises a plurality of solder pins provided at intervals in the lateral direction, the solder pins of the male terminals are provided to align in the longitudinal direction and arranged in a plurality of rows in the lateral direction, and the solder pins in a same row are soldered to a same one of the at least one soldering pad by solders.

19. The connector assembly according to claim 16, wherein each of the cavities is correspondingly provided with four contact portions, and the four contact portions are provided at a same height and are in contact with a same one of the insertion portions.

20. The connector assembly according to claim 16, wherein each of the first elastic arms comprises a first arm, a second arm and a first connecting arm, the first arm and the second arm are provided at an interval in the longitudinal direction and connected by the first connecting arm, each of the first arm and the second arm is provided with one of the contact portions, the one of the contact portions of the first arm is defined as a first contact portion, the one of the contact portions of the second arm is defined as a second contact portion, for two adjacent cavities of the cavities in the lateral direction, the first contact portion and the second contact portion are exposed to different ones of two adjacent cavities in the lateral direction; each of the second elastic arms comprises a third arm, a fourth arm and a second connecting arm, the third arm and the fourth arm are provided at an interval in the lateral direction and connected by the second connecting arm, each of the third arm and the fourth arm is provided with one of the contact portions, the one of the contact portions of the third arm is defined as a third contact portion, the one of the contact portions of the fourth arm is defined as a fourth contact portion, and for two adjacent cavities of the cavities in the longitudinal direction, the third contact portion and the fourth contact portion are exposed to different ones of the two adjacent cavities in the longitudinal direction.
